(19) United States
(12) Patent Application Publication
(10) Pub. No.: US 2007/0170415 A1
(43) Pub. Date: Jul. 26, 2007

(54) Semiconductor light emitting device

(75) Inventor: Hideaki Maruta, Kyoto-shi (JP)

Correspondence Address: HOGAN & HARTSON L.L.P., 1999 AVENUE OF THE STARS, SUITE 1400, LOS ANGELES, CA, 90067, US

(73) Assignee: ROHM CO., LTD., Kyoto (JP)

(21) Appl. No.: 10/583,240

(22) PCT Filed: Jan. 5, 2005
(86) PCT No.: PCT/JP05/00044

§ 371 Date: Jun. 16, 2006

(30) Foreign Application Priority Data
Jan. 7, 2004 (JP) 2004-002377

(51) Int. Cl. H01L 29/06

(52) U.S. Cl. 257/13

(57) ABSTRACT

The refractive index of the material for forming a light emitting element, example of the material including a group III Nitride Compound Semiconductor, is relatively higher than that of air; therefore, in order to emit, into air, light generated in an active layer in conventional semiconductor light emitting devices, it is indispensable that its incidence angle from their semiconductor layer into the air is the critical angle of total reflection or less. If the incidence angle is more than the critical angle of total reflection, the light cannot go out into the air, and is totally reflected. In order to solve the problem, the invention is a semiconductor light emitting device including a substrate, and at least a first semiconductor layer, an active layer and a second semiconductor layer that are sequentially provided on the substrate, wherein the second semiconductor layer has a polarity different from that of the first semiconductor layer, and the total area of the first semiconductor layer, the active layer and the second semiconductor layer in side faces where the active layer is uncovered is 5% or more of the area of the upper face which is uncovered at the side of the second semiconductor layer.

### TECHNICAL FIELD

The present invention relates to a semiconductor light emitting device having a high light emitting efficiency. The invention relates in particular to a semiconductor light emitting device wherein importance is attached to the taking-out of light from its side faces.

### BACKGROUND ART

Conventional semiconductor light emitting devices are composed as illustrated in FIG. 1. FIG. 1 is an example of a GaN based semiconductor light emitting device made of a group III Nitride Compound Semiconductor represented by AlₓGa_{y}In_{1-x-y}N wherein 0≦x≦1, 0≦y≦1, and 0≦x+y≦1. In FIG. 1, 81 represents a p side bonding pad; 82, a p type electrode; 83, a p-GaN semiconductor layer; 85, an InGaN active layer; 86, an n-GaN semiconductor layer; 87, a sapphire substrate; 88, an n side bonding pad; and 89, an n type electrode.

The refractive index of the material for forming a light emitting element, examples of the material including a group III Nitride Compound Semiconductor represented by AlₓGa_{y}In_{1-x-y}N wherein 0≦x≦1, 0≦y≦1, and 0≦x+y≦1, is relatively high compared to that of air. For example, in the GaN based semiconductor light emitting device illustrated in FIG. 1, in order that light generated in the InGaN active layer 85 can go out into the air through the p type electrode 82, it is indispensable that the incidence angle thereof into the air in the p-aN semiconductor layer 83 is not more than the critical angle of total reflection. If the incidence angle is more than the critical angle of total reflection, the light cannot go out into the air so that the light is totally reflected.

The totally reflected light is propagated in the semiconductor light emitting device. The situation of the transmission is illustrated in FIG. 2. FIG. 2 is an example of light propagated in a semiconductor light emitting device having an active layer. In FIG. 2, 91 represents a semiconductor layer; 92, the active layer; 93, a semiconductor layer; 94, the upper face of the semiconductor light emitting device; 95, the bottom face of the semiconductor light emitting device; and 96, a point light source for explaining the propagated light.

Light generated at the position of, e.g., the point light source 96 in the active layer 92 passes through the semiconductor layer 91 and reaches the upper face 94. When the incidence angle thereof is not more than the critical angle of total reflection, the light goes out into the air. When the refractive index of the semiconductor layer 91 is represented by n₀ and that of the air is regarded as 1, the critical angle of total reflection θ₀ is given by the following equation:
θ₀ =sin^{31 1}(1/n₀) (1)
When n_{0 =}2.8, θ_{0 =}21 degrees from the equation (1). If the incidence angle θ is less than 21 degrees, the light goes out from the upper face 94 to the air. The ratio η that the light which goes from the point light source 96 toward the upper face 94 of the semiconductor light emitting device or the light which goes from the point light source 96 toward the bottom face 95 of the semiconductor light emitting device and is then reflected on the bottom face 95 goes out from the upper face 94 of the semiconductor light emitting device into the air is given by the following equation:
η=(1−cos θ₀) (2)
When θ_{0 =}21 degrees in the equation (2), η=7%. When the semiconductor light emitting device is a rectangular parallelepiped, the ratio of light rays going out into the air to light rays towards all directions is: 3η=21%. Thus, 79% of the rays are confined in the semiconductor light emitting device.

However, when the incidence angle θ is 21 degrees or more, light is totally reflected and propagated again in the semiconductor layers 91 and 93. For light generated in the active layer 92, the semiconductor layers 91 and 93 are transparent, but the active layer 92 has a band gap corresponding to the generated light. Thus, the layer 92 may become an absorber therefor. When light is propagated in the semiconductor layers 91 and 93, the light passes through the active layer 92 also. Accordingly, whenever the light passes through the active layer 92, the propagated light is attenuated by absorption loss.

The light reaching side faces of the semiconductor light emitting device is totally reflected again when the incidence angle thereof is 21 degrees or more. Consequently, the light is confined in the semiconductor light emitting device. If the incidence angle is less than 21 degrees, the light goes out into the air. Since the light passing through the active layer 92 many times is attenuated as described above, the intensity of the emitted light also becomes small.

As described above, the rate that light generated in the active layer is confined inside by the total reflection thereof is large, and the light going out from the side faces is also attenuated. The rate that light generated in an active layer can be taken outside is called external quantum efficiency. For such a reason, the external quantum efficiency of conventional semiconductor light emitting devices is bad.

There is a technique wherein in order to reduce total reflection on side faces of a semiconductor light emitting device, the shape of the upper face thereof is made into a triangle (see, for example, Japanese Patent Application Laid-open No. 10-326910). As described above, however, even if the total reflection on the side faces is reduced, it cannot be expected to improve the external quantum efficiency in the case that light going out from the side faces is attenuated.

### DISCLOSURE OF THE INVENTION

An object of the present invention is to improve the external quantum efficiency of a semiconductor light emitting device in order to solve such problems.

Means for Solving the Problems

In order to attain the above-mentioned object, a first aspect of the invention is a semiconductor light emitting device, including a substrate, and at least a first semiconductor layer, an active layer and a second semiconductor layer that are sequentially provided on the substrate, wherein the second semiconductor layer has a polarity different from that of the first semiconductor layer, and the total area of the first semiconductor layer, the active layer and the second semiconductor layer in side faces where the active layer is uncovered is 5% or more of the area of the upper face which is uncovered at the side of the second semiconductor layer.

A second aspect of the invention is a semiconductor light emitting device, including a substrate, and at least a first semiconductor layer, an active layer and a second semiconductor layer that are sequentially provided on the substrate, wherein the second semiconductor layer has a polarity different from that of the first semiconductor layer, and the shortest distance from all points contained in the active layer to side faces where the active layer is uncovered is 40 μm or less.

A third aspect of the invention is a semiconductor light emitting device, including a substrate, and at least two or more mesa portions in each of which a first semiconductor layer, an active layer and a second semiconductor layer that are sequentially provided on the substrate, wherein the second semiconductor layers have a polarity different from that of the first semiconductor layers and further at least the second semiconductor layers and the active layers are spatially separated between the mesa portions.

A fourth aspect of the invention is a semiconductor light emitting device, including a substrate, and at least two or more mesa portions in each of which a first semiconductor layer, an active layer and a second semiconductor layer that are sequentially provided on the substrate, wherein the second semiconductor layers have a polarity different from that of the first semiconductor layers and further except one or more bridge portions for connecting the mesa portions at least the second semiconductor layers and the active layers are spatially separated between the mesa portions.

A fifth aspect of the invention is a semiconductor light emitting device, which sequentially includes at least a substrate, a first semiconductor layer, an active layer, and a second semiconductor layer, wherein the second semiconductor layer has a polarity different from that of the first semiconductor layer, and the upper face which is uncovered at the side of the second semiconductor layer has a concave extending from the uncovered upper face at the side of the second semiconductor layer at least to the active layer.

In the invention, the total area of the first semiconductor layer, the active layer and the second semiconductor layer in the side faces where the active layer is uncovered can be set to 5% or more of the area of the uncovered upper face at the side of the second semiconductor layer.

In the invention, the shortest distance from all points contained in the active layer to the sides where the active layer is uncovered can be set to 40 μm or less.

In the invention, the shape of the uncovered upper face at the side of the second semiconductor layer can give an apex having an angle of less than 45 degrees.

In the invention, one of interior angles made by the side faces where the active layer is uncovered and the uncovered upper face at the side of the second semiconductor layer can be set to 138 degrees or more.

In the invention, the face of the substrate opposite to the face of the substrate where the first semiconductor layer is formed can have a reflecting layer.

In the invention, the semiconductor light emitting device can be rendered a group III Nitride Compound Semiconductor light emitting device represented by AlₓGa_{y}In_{1-x-y}N wherein (0≦x≦1, 0≦y≦1, and 0≦x+y≦1).

The above-mentioned structures of the invention can be combined within a permissible scope.

As described above, according to the invention, the light emitting efficiency of a semiconductor light emitting device can be made high. In particular, the taking-out of light from its side faces can be made excellent.

### BRIEF DESCRIPTION OF THE DRAWINGS

FIG. 1 is a view for explaining the structure of a conventional GaN based semiconductor light emitting device made of a group III Nitride Compound.

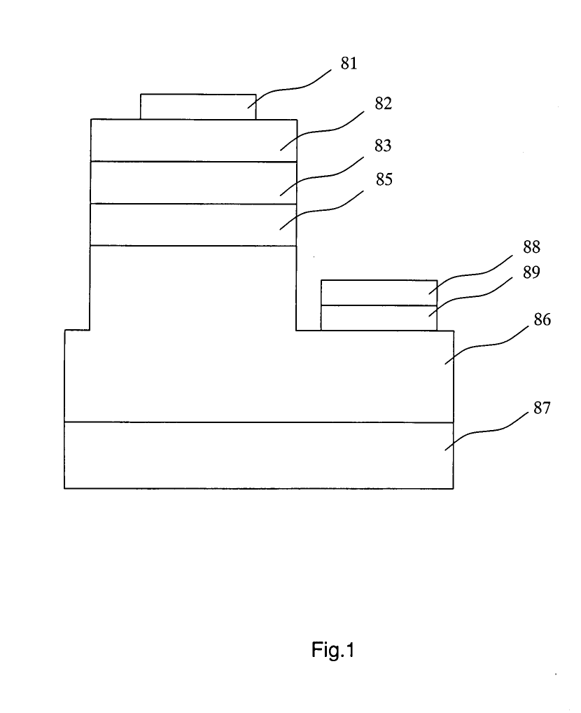

FIG. 2 is a view for explaining an example of light propagated in a semiconductor light emitting device having an active layer.

FIG. 3 is a view for explaining an example of the external form model of the semiconductor light emitting device of the invention.

FIG. 4 is a view for explaining a relationship between the ratio of the total area of side faces of a semiconductor layer in the semiconductor light emitting device of the invention to the area of the upper face and the external quantum efficiency thereof.

FIG. 5 is a view for explaining the principle of the invention.

FIG. 6 is a view for explaining the semiconductor light emitting device of the invention.

FIG. 7 is a view for explaining an example of the structure of the semiconductor light emitting device of the invention.

FIG. 8 is a view for explaining an example of the structure of the semiconductor light emitting device of the invention.

FIG. 9 is a view for explaining an example of the structure of the semiconductor light emitting device of the invention.

FIG. 10 is a view for explaining an example of the structure of the semiconductor light emitting device of the invention.

FIG. 11 is a view for explaining an example of the structure of the semiconductor light emitting device of the invention.

FIG. 12 is a view for explaining an example of the structure of the semiconductor light emitting device of the invention.

FIG. 13 is a view for explaining a relationship of the external quantum efficiency of the semiconductor light emitting device of the invention to the angle of an apex of the upper face of a semiconductor layer therein.

FIG. 14 is a view for explaining an example of the external form model of the semiconductor light emitting device of the invention.

FIG. 15 is a view for explaining an example of the structure he semiconductor light emitting device of the invention.

FIG. 16 is a view for explaining an example of the structure semiconductor light emitting device produced as a working example of the invention.

### DESCRIPTION OF REFERENCE NUMBERS

11 Second semiconductor layer
12 Active layer
13 First semiconductor layer
14 Substrate
15 Uncovered upper face at the side of the second semiconductor layer
16 Uncovered side face of the active layer
17 Uncovered side face of the active layer
20 Mesa portion
21, 22 Bonding pads
23 Bridge portion
24 Shelf portion
25 Reflecting layer
26 Point light source
27 Concave
28 Point light source
50 Points contained in the active layer
51 Distances to side faces
31, 39 Ti/Au bonding pads
32 Ni/Au p type electrode
33 p-GaN:Mg contact layer
34 AlₓGa₁₋ₓN:Mg semiconductor layer
35 In_{1-y}Ga_{y}N active layer
36 n-GaN:Si high-temperature buffer layer
37 GaN low-temperature buffer layer
38 Sapphire substrate
40 Al/Au n type electrode
41 SiO₂Passivation film
42 Metal reflecting layer
81 p Side Bonding pad
82 p Type electrode
83 p-GaN semiconductor layer
85 InGaN active layer
86 n-GaN semiconductor layer
87 Sapphire substrate
88 n Type bonding pad
89 n Type electrode
91 Semiconductor layer
92 Active layer
93 Semiconductor layer
94 Upper face of a semiconductor light emitting device
95 Bottom face of the semiconductor light emitting device
96 Point light source

### BEST MODE FOR CARRYING OUT THE INVENTION

With reference to the attached drawings, embodiments of the present invention will be described hereinafter.

### EMBODIMENT 1

The present embodiment is a semiconductor light emitting device including a substrate, and at least a first semiconductor layer, an active layer and a second semiconductor layer that are sequentially provided on the substrate, wherein the second semiconductor layer has a polarity different from that of the first semiconductor layer, and the ratio of the total area of the first semiconductor layer, the active layer and the second semiconductor layer in side faces where the active layer is uncovered to the area of the upper face which is uncovered at the side of the second semiconductor layer is made large, thereby enlarging the external quantum efficiency.

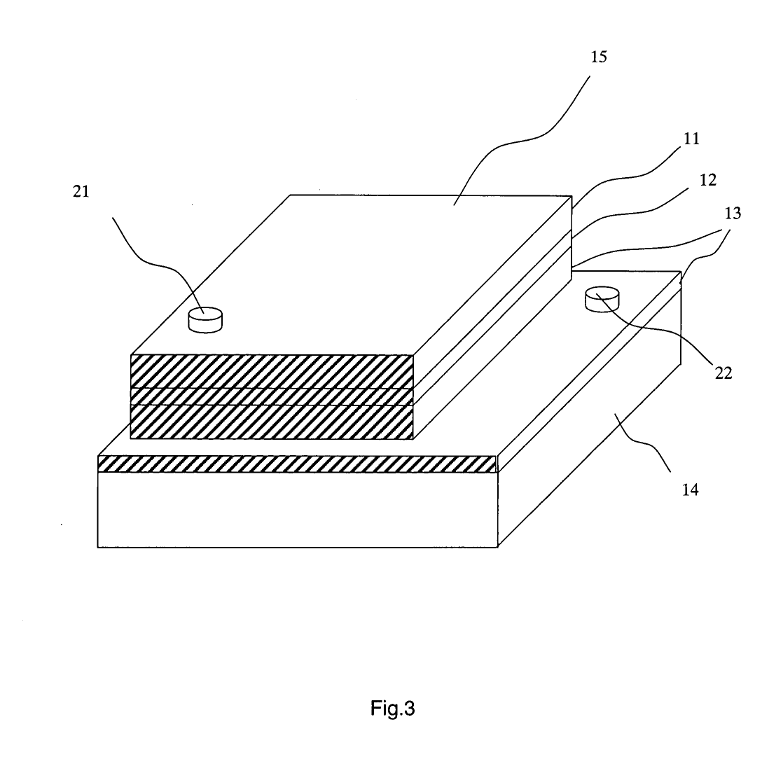

FIG. 3 is a view for explaining an example of the external form model of the semiconductor light emitting device of the invention. In FIG. 3, 11 represents a second semiconductor layer; 12, an active layer; 13, a first semiconductor layer; 14, a substrate; 15, an uncovered upper face at the side of the second semiconductor layer; 17, a side where the active layer is uncovered; and 21 and 22, bonding pads.

In a nitride based semiconductor light emitting device made of a group III Nitride Compound represented by AlₓGa_{y}In_{1-x-y}N wherein (0≦x≦1, 0≦y≦1, and 0≦x+y≦1), the following case may be adopted: a GaN buffer layer, an n-GaN first semiconductor layer, a GaInN active layer, and a p-GaN second semiconductor layer are stacked onto a sapphire substrate; and in order to form an n type electrode, a part of the n-GaN first semiconductorlayer, theGaInNactivelayer, andthep-GaNsecond semiconductor layer are made naked by etching. In this case, a part of the n-GaN first semiconductor layer remains without being etched. In the present specification, the side face 17 includes a side face of the remaining first semiconductor layer. In FIG. 3, the side face 17 where the active layer 12 is uncovered is a portion corresponding to shaded portions shown in FIG. 3, and includes a side face of the substrate 14, and a side face of the remaining part of the first semiconductor layer 13 on the substrate 14. The shaded portions of the side face 17 shown in FIG. 3 illustrate only one of side faces of the semiconductor light emitting device. In the specification, this matter is correspondingly applied to the following.

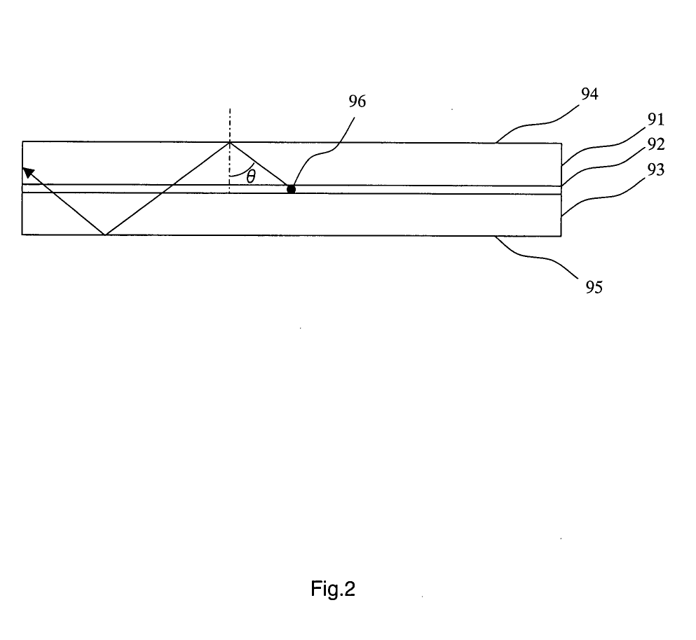

In FIG. 3, the first semiconductor layer 13, the active layer 12, and the second semiconductor layer 11 are formed on the substrate 14. The second semiconductor layer 11 and the first semiconductor layer 13 are each a p type or n type semiconductor layer, and further polarities thereof are different from each other. At this time, holes supplied from the p type semiconductor layer are recombined with electrons supplied from the n type semiconductor layer in the active layer 12 so as to generate light. As described with reference to FIG. 2, the generated light goes out from the upper face 15 at the side of the second semiconductor layer 11, or is propagated in the first semiconductor layer 13 and the second semiconductor layer 11 so as to go out from the side faces.

In the present embodiment, about a nitride based compound semiconductor wherein the second semiconductor layer 11 was made of a GaN layer (refractive index: 2.8, and transmissivity: 100%) 0.3 μm thick and an AlGaN layer (refractive index: 2.65, and transmissivity: 100%) 0.01 μm thick; the active layer 12 was made of a GaInN layer (refractive index: 2.8, and transmissivity: 95.5%) 0.1 μm thick; the first semiconductor layer 13 was made of a GaN layer (refractive index: 2.8, and transmissivity: 100%) 0.6 μm thick; andthe substrate 14 was made of a sapphire substrate (refractive index: 1.8, and transmissivity: 100%) in FIG. 3, the external quantum efficiency was obtained by simulation in the state that the reflectivity of the bottom face of the first semiconductor layer 13 was set to 100%.

According to the shape of conventional semiconductor light emitting devices, the area of the upper face is about 300 μm×300 μm and the area of one out of the side faces is about 300 μm×1 μm. Thus, the ratio of the total area of the side faces 17 to the upper face 15 is 1.4%. When the external quantum efficiency at this time is regarded as 1, in Table 1 is shown a relationship between the ratio of the total area of the side faces 17 to the area of the upper face 15 and the relative external quantum efficiency.

TABLE 1

| | Total area of | |
|---|---|---|
| | the side | External quantum |
| | faces/area of | efficiency |
| Shape | the upper face | (relative value) |
| Prior art (square) | 1.4% | 1 |
| Circle | 13% | 1.09 |
| Square | 14% | 1.08 |
| Triangle (apex angle: 60°) | 17% | 1.12 |
| Triangle (apex angle: 40°) | 18% | 1.11 |
| Triangle (apex angle: 20°) | 21% | 1.15 |

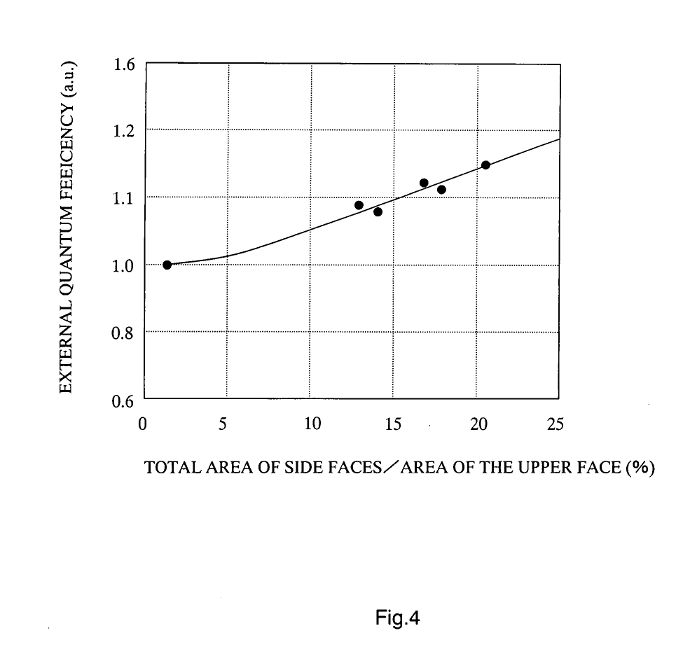

The external quantum efficiency to (the total area of the side faces/the area of the upper face) in Table 1 is shown in FIG. 4. As illustrated in FIG. 4, as the ratio of the total area of the side faces 17 to the area of the upper face 15 is increased, the external quantum efficiency tends to be improved regardless of the shape of the upper face. It is understood that in particular when the ratio of the total area of the side faces 17 to the area of the upper face 15 is more than 5%, the external quantum efficiency is largely improved. This appears to be because light going out from the side faces is not attenuated, thereby making the external quantum efficiency high.

Accordingly, in the semiconductor light emitting device including the substrate 14, and at least the first semiconductor layer 13, the active layer 12 and the second semiconductor layer 11 that are sequentially provided on the substrate 14, wherein the second semiconductor layer 11 has a polarity different from that of the first semiconductor layer 13, and the total area of the first semiconductor layer 13, the active layer 12 and the second semiconductor layer 11 in the side faces where the active layer 12 is uncovered is 5% or more of the area of the upper face 15 which is uncovered at the side of the second semiconductor layer 11, the external quantum efficiency can be made large.

### EMBODIMENT 2

The present embodiment is a semiconductor light emitting device including a substrate, and a first semiconductor layer, an active layer and a second semiconductor layer that are sequentially provided on the substrate, wherein the second semiconductor layer has a polarity different from that of the first semiconductor layer, and the shortest distance from all points contained in the active layer to side faces where the active layer is uncovered is made short, thereby enlarging the external quantum efficiency.

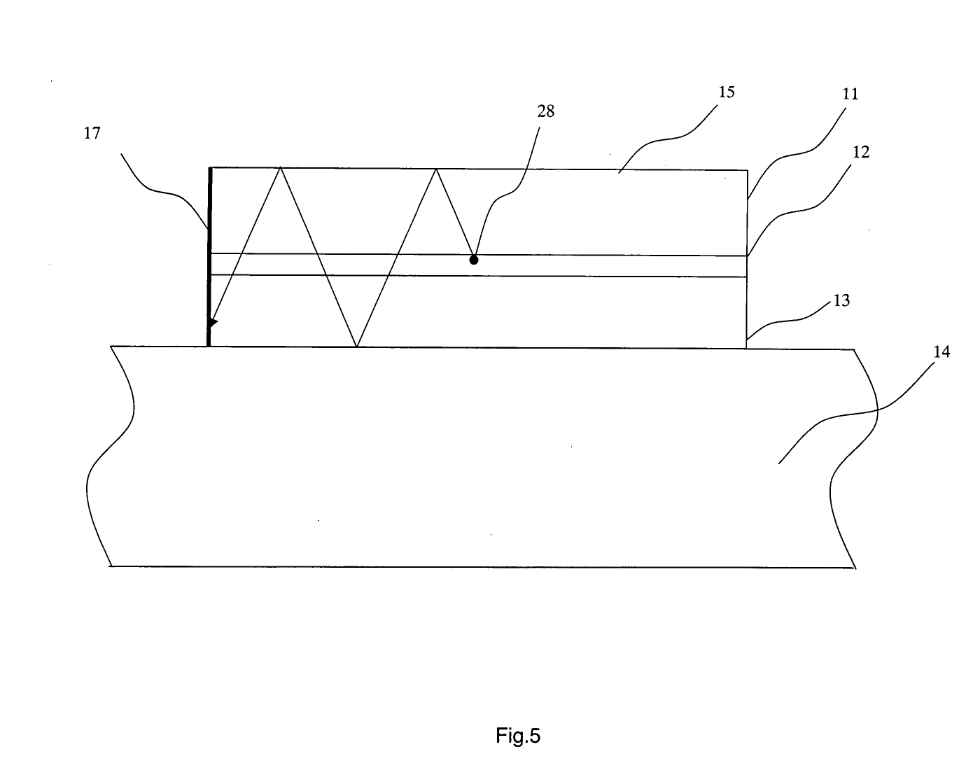

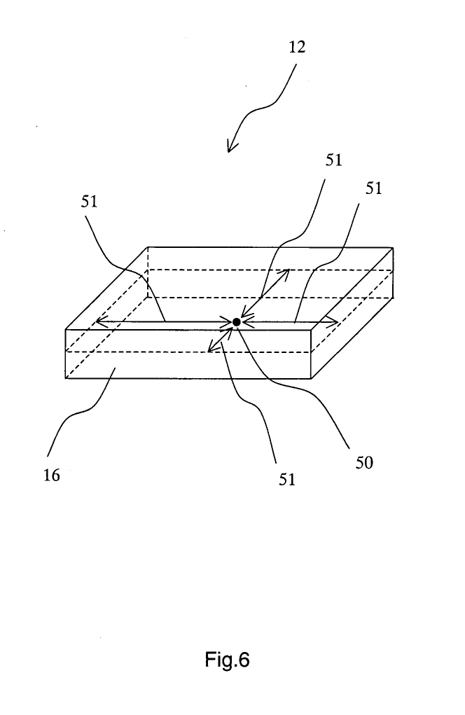

FIG. 5 is a view for explaining the principle of the present invention. FIG. 6 is an explanatory view of the invention. In FIGS. 5 and 6, 11 represents a second semiconductor layer; 12, an active layer; 13, a first semiconductor layer; 14, a substrate; 15, an uncovered upper face of the second semiconductor layer; 17, a side face where the active layer is uncovered; and 28, a point light source. The point light source 28 is an imaginary point, at the position of which light is generated. In FIG. 6, 16 represents side faces where the active layer is uncovered; 50, a point contained in the active layer; and 51, distances from the point 50 to the side faces 16.

In FIG. 5, the first semiconductor layer 13, the active layer 12, and the second semiconductor layer 11 are formed on the substrate 14. The second semiconductor layer 11 and the first semiconductor layer 13 are each a p type or n type semiconductor layer, and further polarities thereof are different from each other. At this time, holes supplied from the p type semiconductor layer are recombined with electrons supplied from the n type semiconductor layer in the active layer 12 so as to generate light. As described with reference to FIG. 2, the light from the point light source 28 goes out from the upper face at the side of the second semiconductor layer 11, or is propagated in the second semiconductor layer 11 and the first semiconductor layer 13 so as to go out from the side faces in FIG. 5. At this time, the light from the point light source 28 goes across the active layer 12 many times. The active layer 12 emits light having a wavelength corresponding to the energy obtained by the recombination of the electrons with the holes. In other words, when light of the wavelength conversely passes through the active layer 12, the active layer 12 becomes an absorber for the light of the wavelength so that the light is attenuated.

In conventional semiconductor light emitting devices, the width of their semiconductor layer is relatively larger than the thickness of the semiconductor layer; therefore, the distance at which light generated in their active layer reaches side faces of the semiconductor layer is large and the number of times of the phenomenon that the light is reflected on boundary faces between the semiconductor layer and the outside and then goes across the active layer is large. For this reason, when the light goes out from the side faces of the semiconductor layer, the light is attenuated so that a sufficient external quantum efficiency cannot be obtained.

In the embodiment, the distances 51 from the point 50 contained in the active layer 12 in FIG. 6 to the side faces 16 are made short, thereby making it possible to decrease the number of times of the phenomenon that light generated in the active layer 12 goes across the active layer 12 until the light reaches the side faces 16 so as to make the attenuation amount of the light small. In short, the emission efficiency of light going out from the side faces 16 is made high so that the external quantum efficiency can be improved.

It has been understood from results of repeated experiments in the embodiment that the external quantum efficiency can be largely improved when the shortest distance from the point 50 contained in the active layer 12 to the side faces 16 is 40 μm or less in FIG. 6. The shortest distance is the shortest among the distances 51 from the point 50 to the side faces 16.

Accordingly, in the semiconductor light emitting device including the substrate 14, and at least the first semiconductor layer 13, the active layer 12 and the second semiconductor layer 11 that are sequentially provided on the substrate 14, wherein the second semiconductor layer 11 has a polarity different from that of the first semiconductor layer 13, and the shortest distance from all points 50 contained in the active layer 12 to the side faces 16 where the active layer 12 is uncovered is 40 μm or less, the external quantum efficiency can be made large.

### EMBODIMENT 3

The present embodiment is a semiconductor light emitting device including a substrate, and at least two or more mesa portions in each of which a first semiconductor layer, an active layer and a second semiconductor layer that are sequentially provided on the substrate, wherein the second semiconductor layers have a polarity different from that of the first semiconductor layers and further at least the second semiconductor layers and the active layers are spatially separated between the mesa portions, thereby enlarging the external quantum efficiency.

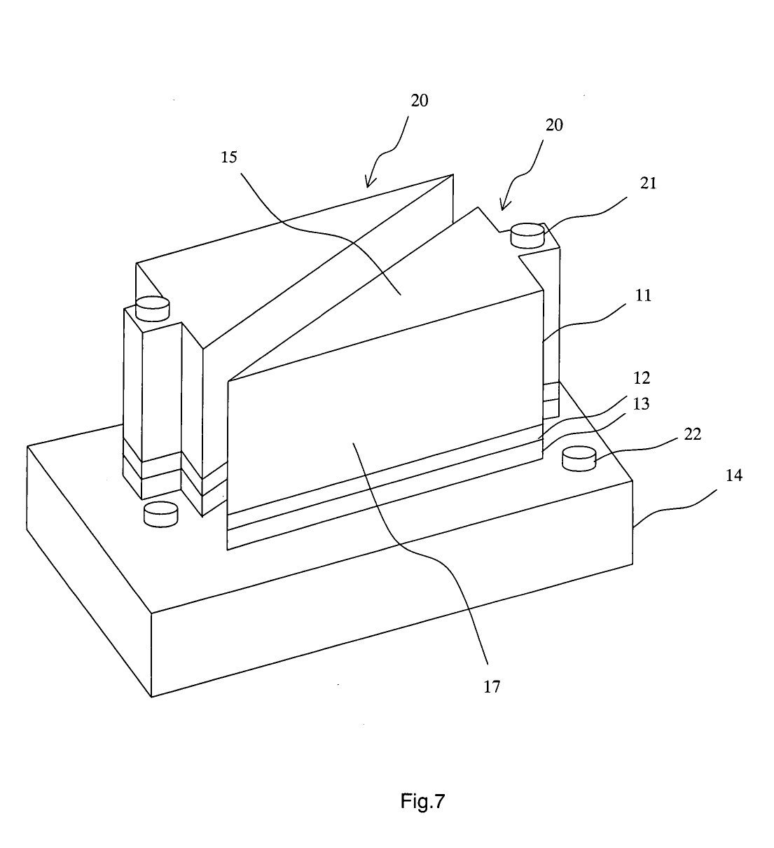

FIG. 7 illustrates an example of the structure of the semiconductor light emitting device of the invention. In FIG. 7, 11 represents a second semiconductor layer; 12, an active layer; 13, a first semiconductor layer; 14, a substrate; 15, an uncovered upper face of the second semiconductor layer; 17, a side face where the active layer is uncovered; 20, mesa portions; and 21 and 22, bonding pads. In FIG. 7, two the mesa portions 20, wherein the shape of the upper face 15 is a triangle are formed on the substrate 14. The number of the mesa portions 20 on the substrate 14 is not limited to two, and it is sufficient that the number is plural. The mesa portions 20 can be formed by stacking the semiconductor layers including the active layer 12 onto the substrate 14 and then etching the layers except portions which will be the mesa portions 20.

In FIG. 7, at least the first semiconductor layer 13, the active layer 12 and the second semiconductor layer 11 are formed in each of the mesa portions 20 on the substrate 14. Electric current is supplied from the bonding pad 21 formed on the second semiconductor layer 11 to the second semiconductor layer 11 and from the bonding pad 22 formed on the substrate 14 to the first semiconductor layer 13. The second semiconductor layer 11 and the first semiconductor layer 13 are each a p type or n type semiconductor layer, and further polarities thereof are different from each other. At this time, holes supplied from the p type semiconductor layer are recombined with electrons supplied from the n type semiconductor layer in the active layer 12 so as to generate light. As described with reference to FIG. 2, the generated light goes out from the upper face at the side of the second semiconductor layer 11 in each of the mesa portions 20, or is propagated in the second semiconductor layer 11 and the first semiconductor layer 13 so as to go out from the side faces in each of the mesa portions 20.

In the case that plural very small mesa portions are formed on a substrate as illustrated in FIG. 7, the light emission efficiency becomes higher than in the case that a large mesa portion is formed since light propagated in the first semiconductor layer 13 and the second semiconductor layer 11 goes out from the side faces of each of the mesa portions 20 before the light is absorbed in the active layer 12. As a result, the external quantum efficiency is largely improved.

In the semiconductor light emitting device according to the embodiment also, the external quantum efficiency is largely improved when the ratio of the total area of the side faces 17 to the area of the upper face 15 is 5% or more, as described in Embodiment 1.

In the semiconductor light emitting device according to the embodiment also, the external quantum efficiency is largely improved when the shortest distance from points contained in the active layer 12 to the side faces where the active layer 12 is uncovered is 40 82 m or less, as described in Embodiment 2.

In FIG. 7, on the substrate 14, the first semiconductor layer 13 partially remains without being etched. Accordingly, the bonding pad 22 is formed on the substrate 14. Of course, if the substrate 14 is made of an electric conductor, the bonding pad 22 can be formed on the substrate 14 even if a part of the first semiconductor layer 13 is not left. Furthermore, common bonding pads may be used. In the case that the substrate is not electrically conductive and a part of the first semiconductor layer 13 is not left on the substrate 14, it is advisable that the bonding pad 22 is formed on a shelf portion or the like that is formed to be fitted to the first semiconductor layer 13, so as to be connected to the first semiconductor layer 13.

Accordingly, in the semiconductor light emitting device including the substrate 14, and at least the two or more mesa portions in each of which the first semiconductor layer 13, the active layer 12 and the second semiconductor layer 11 that are sequentially provided on the substrate 14, wherein the second semiconductor layers 11 have a polarity different from that of the first semiconductor layers 13 and further the second semiconductor layers 11 and the active layers 12 are spatially separated between the mesa portions, the ratio of the total area of the side faces 17 to the area of the upper face 15 can be made large; therefore, the external quantum efficiency can be largely improved. In the semiconductor light emitting device of the embodiment, the shortest distance from points contained in the active layer 12 to the side faces where the active layer is uncovered can also be made short; therefore, the external quantum efficiency can be largely improved.

Furthermore, in the semiconductor light emitting device wherein the ratio of the total area of the side faces 17 to the area of the upper face 15 is 5% or more, or in the semiconductor light emitting device wherein the shortest distance from all points contained in the active layer 12 to the side faces where the active layer 12 is uncovered is 40 μm or less, light going out from the side faces is not easily attenuated; therefore, the external quantum efficiency can be made large.

### EMBODIMENT 4

The present embodiment is a semiconductor light emitting device including a substrate, and at least two or more mesa portions in each of which a first semiconductor layer, an active layer and a second semiconductor layer that are sequentially provided on the substrate, wherein the second semiconductor layers have a polarity different from that of the first semiconductor layers and further except bridge portions for connecting the mesa portions the second semiconductor layers and the active layers are spatially separated between the mesa portions, thereby enlarging the external quantum efficiency.

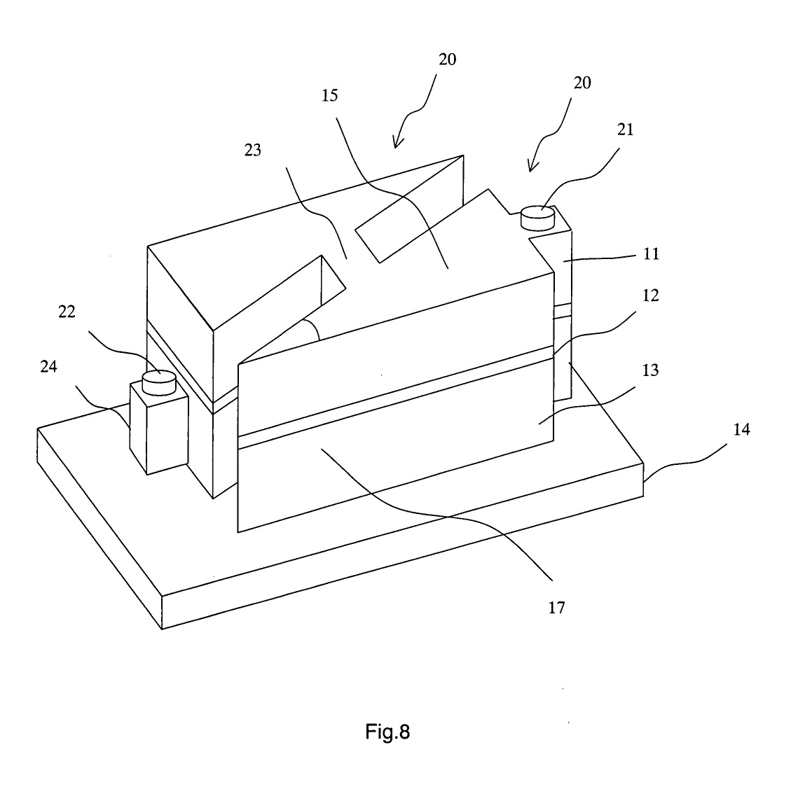

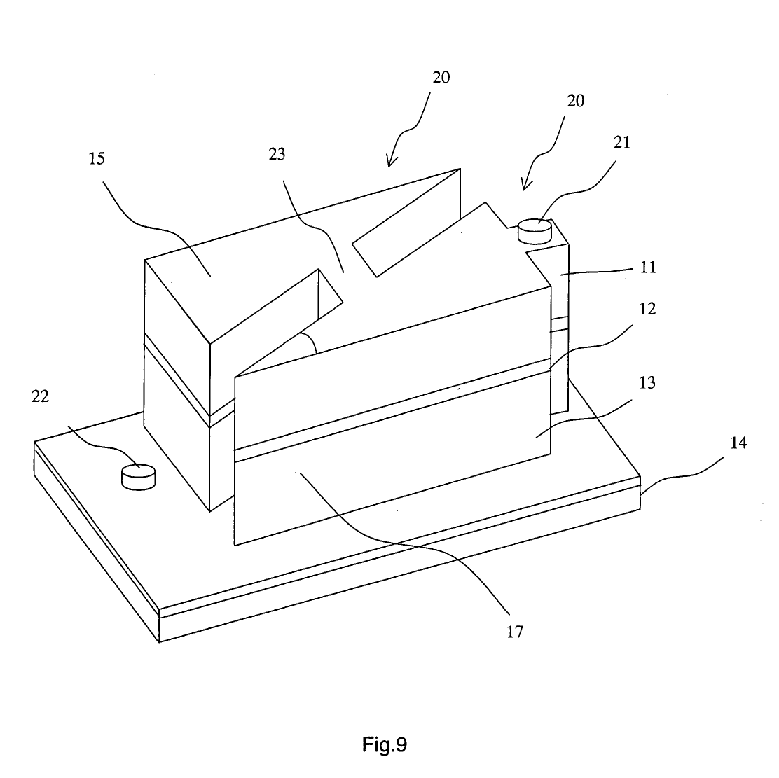

FIGS. 8 and 9 illustrate examples of the structure of the semiconductor light emitting device of the invention. In FIGS. 8 and 9, 11 represents a second semiconductor layer; 12, an active layer; 13, a first semiconductor layer; 14, a substrate; 15, an uncovered upper face at the side of the second semiconductor layer; 17, a side face where the active layer is uncovered; 20, mesa portions; 21 and 22, bonding pads; 23, a bridge portion; and 24, a shelf portion. In FIGS. 8 and 9, two the mesa portions 20, wherein the shape of the upper face 15 is a triangle are formed on the substrate 14. The number of the mesa portions 20 on the substrate 14 is not limited to two, and it is sufficient that the number is plural. The two mesa portions are connected to each other through the bridge portion 23.

The bridge portion 20 is a portion for electrically connecting the mesa portions 20 formed on the substrate to each other, and can be formed by stacking the semiconductor layers including the active layer 12 onto the substrate 14 and then etching the layers except portions which will be the mesa portions 20 or the bridge portion 23. The present embodiment is an embodiment in forms separated except a part of the active layer 12 in each of the mesa portions 20, that is, portions connected through the bridge portion 20 in the semiconductor light emitting device described in Embodiment 3.

In FIG. 8, at least the first semiconductor layer 17, the active layer 12 and the second semiconductor layer 11 are formed in each of the mesa portions 20 on the substrate 14. Electric current is supplied from the bonding pad 21 formed on one of the second semiconductor layers 11 to the second semiconductor layers 11 in the two mesa portions 20 and from the bonding pad 22 formed on the shelf portion 24 to the first semiconductor layers 13 in the two mesa portions 20. The second semiconductor layers 11 are p type or n type semiconductor layers in the same manner as the first semiconductor layers 13, and further the polarity of the second semiconductor layers is different from that of the first semiconductor layers. At this time, holes supplied from the p type semiconductor layers are recombined with electrons supplied from the n type semiconductor layers in the active layers 12 so as to generate light. As described with reference to FIG. 2, the generated light goes out from the upper face at the side of the second semiconductor layer 11 in each of the mesa portions 20, or is propagated in the second semiconductor layer 11 and the first semiconductor layer 13 so as to go out from the side faces in each of the mesa portions 20.

In FIG. 8, the second semiconductor layers 11 and the first semiconductor layers 13 in the two mesa portions 20 are connected through the bridge portion 23, whereby the mesa portions 20 are electrically connected to each other. It is therefore sufficient that the single bonding pad 21 and the single bonding pad 22 are present. Thus, the process for producing the semiconductor light emitting device becomes simple. Since the substrate 14 in FIG. 8 is not electrically conductive and a part of the first semiconductor layers 13 are not left on the substrate 14, the bonding pad 22 is formed on the shelf portion 24 formed to be fitted to one of the first semiconductor layers 13, so as to be connected to the first semiconductor layers 13.

In FIG. 9, at least the first semiconductor layer 17, the active layer 12 and the second semiconductor layer 11 are formed in each of the mesa portions 20 on the substrate 14. Electric current is supplied from the bonding pad 21 formed on one of the second semiconductor layers 11 to the second semiconductor layers 11 in the two mesa portions 20 and from the bonding pad 22 formed on the substrate 14 to the first semiconductor layers 13 in the two mesa portions 20. The second semiconductor layers 11 are p type or n type semiconductor layers in the same manner as the first semiconductor layers 13, and further the polarity of the second semiconductor layers 11 is different from that of the first semiconductor layers 13. At this time, holes supplied from the p type semiconductor layers are recombined with electrons supplied from the n type semiconductor layers in the active layers 12 so as to generate light. As described with reference to FIG. 2, the generated light goes out from the upper face at the side of the second semiconductor layer 11 in each of the mesa portions, or is propagated in the second semiconductor layer 11 and the first semiconductor layer 13 so as to go out from the side faces in each of the mesa portions 20.

In FIG. 9, the second semiconductor layers 11 and the first semiconductor layers 13 in the two mesa portions 20 are connected through the bridge portion 23; therefore, it is sufficient that the single bonding pad 21 and the single bonding pad 22 are present. Thus, the process for producing the semiconductor light emitting device becomes simple. Since parts of the first semiconductor layers 13 are left on the substrate 14 in FIG. 9 without being etched, the bonding pad 22 can be formed on the substrate 14. of course, if the substrate 14 is made of an electric conductor, the bonding pad 22 can be formed on the substrate 14 even if a part of the first semiconductor layers 13 are not left.

In the embodiment, the same advantageous effects as described in Embodiment 3 are obtained and further common bonding pads can be used.

### EMBODIMENT 5

The present embodiment is a semiconductor light emitting device which sequentially includes at least a substrate, a first semiconductor layer, an active layer, anda second semiconductor layer, wherein the second semiconductor layer has a polarity different from that of the first semiconductor layer, and the upper face which is uncovered at the side of the second semiconductor layer has a concave extending from the uncovered upper face at the side of the second semiconductor layer at least to the active layer, thereby enlarging the external quantum efficiency.

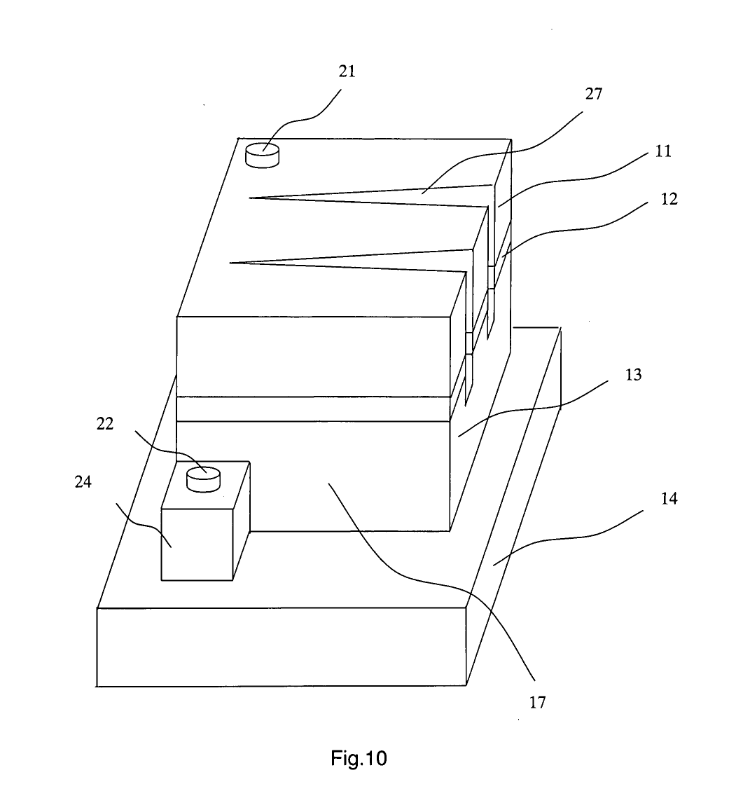

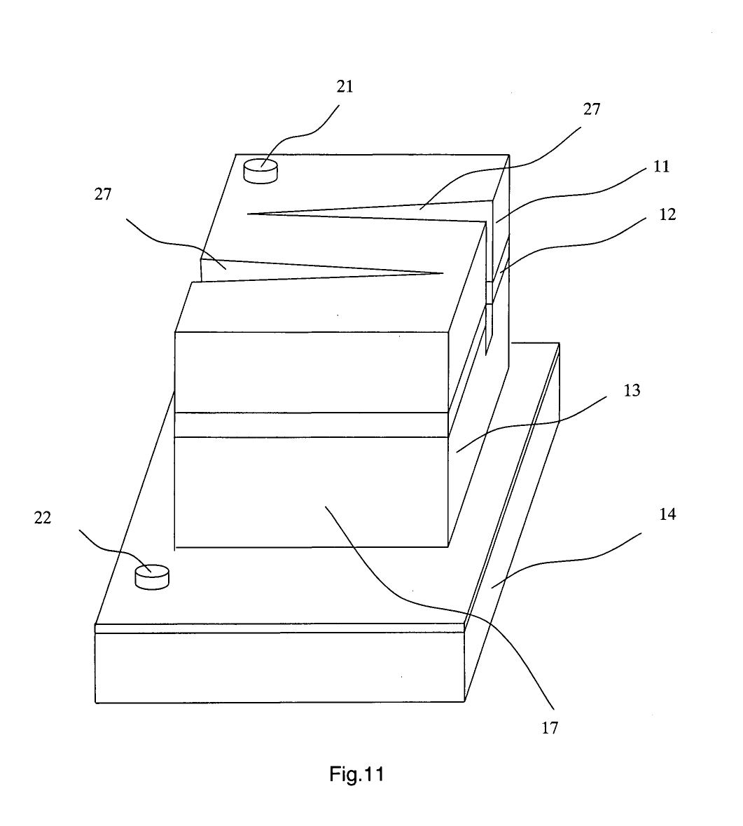

FIGS. 10 and 11 illustrate examples of the structure of the semiconductor light emitting device of the invention. In FIGS. 10 and 11, 11 represents a second semiconductor layer; 12, an active layer; 13, a first semiconductor layer; 14, a substrate; 17, a side face where the active layer is uncovered; 21 and 22, bonding pads; 24, a shelf portion; and 27, a concave. In FIGS. 10 and 11, two concaves 27 having a depth reaching at least the active layer 12 are provided. The number of the concaves 27 in the upper face at the side of the second semiconductor layer 11 is not limited to two, and it is sufficient that the number is one or more. The concaves 27 can be made by stacking the semiconductor layers including the active layer 12 onto the substrate 14 and then etching the layers. About the shape and the arrangement of the concaves 27, concaves 27 having a triangular shape having an acute angle are rendered those illustrated in FIGS. 10 and 11, but these are an example in the present embodiment. About the shape and the arrangement of the concaves 27, various ones can be used.

In FIG. 10, the first semiconductor layer 17, the active layer 12 and the second semiconductor layer 11 are formed on the substrate 14. Electric current is supplied from the bonding pad 21 formed on the second semiconductor layer 11 to the second semiconductor layer 11 and from the bonding pad 22 formed on the shelf portion 24 to the first semiconductor layer 13. The second semiconductor layer 11 and the first semiconductor layer 13 are each a p type or n type semiconductor layer. Polarities thereof are different from each other. At this time, holes supplied from the p type semiconductor layer are recombined with electrons supplied from the n type semiconductor layer in the active layer 12 so as to generate light. As described with reference to FIG. 2, the generated light goes out from the upper face at the side of the second semiconductor layer 11, or is propagated in the second semiconductor layer 11 and the first semiconductor layer 13 so as to go out from the side faces in each of the semiconductor layers.

As illustrated in FIG. 10, side faces where the active layer 12 is uncovered are newly formed by making the one or more concaves 27, and thus light propagated in the first semiconductor layer 13 and the second semiconductor layer 11 goes out from the newly formed side faces before the light is absorbed in the active layer 12, so that the light emission efficiency becomes high. Consequently, the external quantum efficiency is largely improved.

In the semiconductor light emitting device according to the embodiment also, the external quantum efficiency is largely improved when the ratio of the total area of the side faces 17 to the area of the upper face 15 is 5% or more, as described in Embodiment 1.

In the semiconductor light emitting device according to the embodiment also, the external quantum efficiency is largely improved when the shortest distance from points contained in the active layer 12 to the side faces where the active layer 12 is uncovered is 40 82 m or less, as described in Embodiment 2.

In FIG. 10, the second semiconductor layer 11 and the first semiconductor layer 13 are electrically connected to each other. It is therefore sufficient that the single bonding pad 21 and the single bonding pad 22 are present. Thus, the process for producing the semiconductor light emitting device becomes simple. Since the substrate 14 in FIG. 10 is not electrically conductive and a part of the first semiconductor layer 13 is not left on the substrate 14, it is indispensable that the bonding pad 22 is formed on the shelf portion 24 formed to be fitted to the first semiconductor layer 13, so as to be connected to the first semiconductor layer 13.

In FIG. 11, the first semiconductor layer 13, the active layer 12 and the second semiconductor layer 11 are formed on the substrate 14. Electric current is supplied from the bonding pad 21 formed on the second semiconductor layer 11 to the second semiconductor layer 11 and from the bonding pad 22 formed on the substrate 14 to the first semiconductor layer 13. The second semiconductor layer 11 and the first semiconductor layer 13 are each a p type or n type semiconductor layer. Polarities thereof are different from each other. At this time, holes supplied from the p type semiconductor layer are recombined with electrons supplied from the n type semiconductor layer in the active layer 12 so as to generate light. As described with reference to FIG. 2, the generated light goes out from the upper face at the side of the second semiconductor layer 11, or is propagated in the second semiconductor layer 11 and the first semiconductor layer 13 so as to go out from the side faces in each of the semiconductor layers.

In FIG. 11, the second semiconductor layer 11 and the first semiconductor layer 13 are electrically connected to each other. It is therefore sufficient that the single bonding pad 21 and the single bonding pad 22 are present. Thus, the process for producing the semiconductor light emitting device becomes simple. Since a part of the first semiconductor layer 13 is left on the substrate 14 in FIG. 11 without being etched, the bonding pad 22 can be formed on the substrate 14. Of course, if the substrate 14 is made of an electric conductor, the bonding pad 22 can be formed on the substrate 14 even if a part of the first semiconductor layer 13 is not left.

Accordingly, the present embodiment is the semiconductor light emitting device which sequentially includes at least the substrate 14, the first semiconductor layer 17, the active layer 12, and the second semiconductor layer 11, wherein the second semiconductor 11 has a polarity different from that of the first semiconductor layer 13, and the upper face 15 which is uncovered at the side of the second semiconductor layer 11 has the concave, which extends from the uncovered upper face 15 at the side of the second semiconductor layer 11 at least to the active layer 12, thereby enlarging the ratio of the total area of the side faces 17 to the upper face 15 so that the external quantum efficiency can be improved. Moreover, in the semiconductor light emitting device of the embodiment, the shortest distance from points contained in the active layer 12 to the sides where the active layer is uncovered can be made short; therefore, the external quantum efficiency can be improved.

In the semiconductor light emitting device wherein the ratio of the total area of the side faces 17 to the area of the uncovered upper face 15 at the side of the second semiconductor layer 11 is 5% or more, or in the semiconductor light emitting device wherein the shortest distance from all points contained in the active layer 12 to the side faces of the semiconductor layers where the active layer 12 is uncovered is 40 μm or less, light going out from the side faces is not easily attenuated; therefore, the external quantum efficiency can be made large. Furthermore, common bonding pads can be used since the semiconductor layers are electrically connected to each other even if the concaves 27 are made.

### EMBODIMENT 6

The present embodiment is a semiconductor light emitting device which sequentially includes at least a substrate, a first semiconductor layer, an active layer, and a second semiconductor layer, wherein the second semiconductor layer has a polarity different from that of the first semiconductor layer, and the shape of the upper face which is uncovered at the side of the second semiconductor layer has an apex having an angle of less than 45 degrees, thereby enlarging the external quantum efficiency.

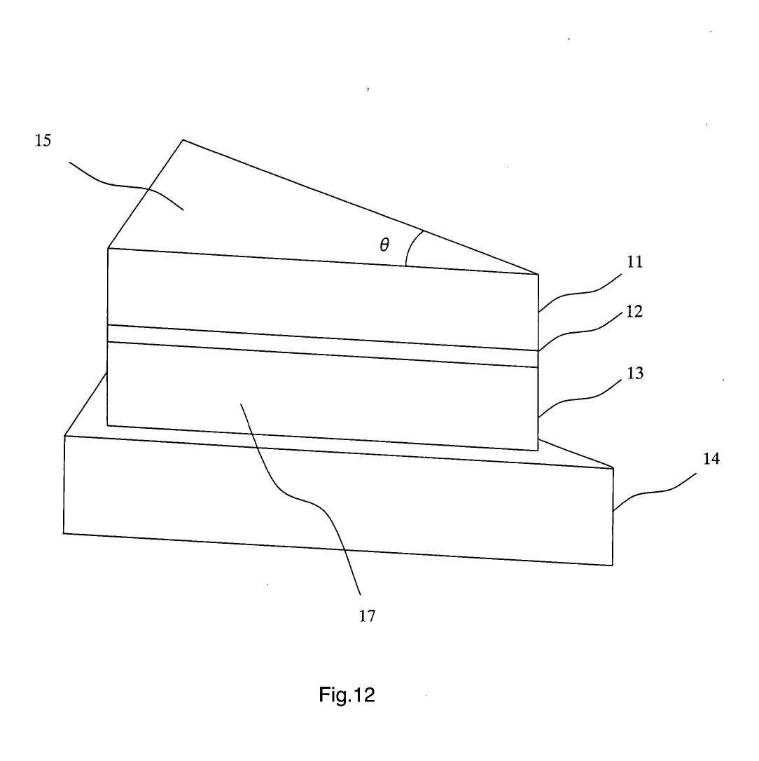

An example of the structure of the semiconductor light emitting device of the invention is illustrated in FIG. 12. In FIG. 12, 11 represents a second semiconductor layer; 12, an active layer; 13, a first semiconductor layer; 14, a substrate; 15, an uncovered upper face at the side of the second semiconductor layer; and 17, a side face where the active layer is uncovered. In FIG. 12, the shape of the upper face 15 is a triangle. The shape is not limited to the triangle, and may be a polygon. Such a shape can be formed by stacking the semiconductor layers including the active layer 12 onto the substrate 14 and then etching the layers.

The second semiconductor layer 11 and the first semiconductor layer 13 are each a p type or n type semiconductor layer. Polarities thereof are different from each other. At this time, holes supplied from the p type semiconductor layer are recombined with electrons supplied from the n type semiconductor layer in the active layer 12 so as to generate light. As described with reference to FIG. 2, the generated light goes out from the upper face of the active layer 12 at the side of the second semiconductor layer 11, or is propagated in the second semiconductor layer 11 and the first semiconductor layer 13 so as to go out from the side faces where the active layer 12 is uncovered.

In FIG. 12, the shape of the upper face 15 has an apex having an angle θ. In the embodiment, about a nitride semiconductor light emitting device wherein the second semiconductor layer 11 was combined of a GaN layer (refractive index: 2.8, and transmissivity: 100%) 0.3 μm thick and an AlGaN layer (refractive index: 2.65, and transmissivity: 100%) 0.01 μm thick; the active layer 12 was made of a GaInN layer (refractive index: 2.8, and transmissivity: 97.5%) 0.1 μm thick; the first semiconductor layer 13 was made ofaGaN layer (refractive index: 2.8, and transmissivity: 100%) 0.6 μm thick; and the substrate 14 was made of a sapphire substrate (refractive index: 1.8, and transmissivity: 100%) in FIG. 12, the external quantum efficiency was obtained by simulation using the angle θ of the apex as a parameter when the total area of the side faces 17 to the upper face 15 was set to 20% in the state that the reflectivity of the bottom face of the first semiconductor layer 13 was set to 100%.

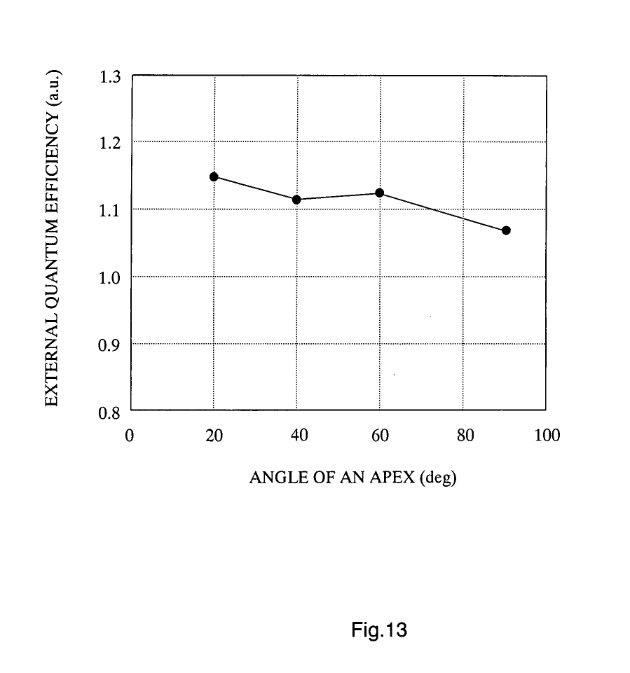

The shape of conventional semiconductor light emitting devices is a square wherein the total area of the side faces 17 to the area of the upper face 15 is 1.4%. When the external quantum efficiency at this time is regarded as 1, in FIG. 13 is shown a relationship between the angle of the apex of the upper face and the external quantum efficiency. As shown in FIG. 13, the external quantum efficiency is improved when the angle of the apex is 45 degrees or less.

Accordingly, in the semiconductor light emitting device wherein the semiconductor layers including the active layer 12 are formed on the substrate 14, the second semiconductor layer 11 has a polarity different from that of the first semiconductor layer 13, and the shape of the uncovered upper face 15 at the side of the second semiconductor layer 11 has an apex having an angle of less than 45 degrees, the external quantum efficiency can be made large. In particular, in the semiconductor light emitting device wherein the shortest distance from all points contained in the active layer 12 to the side faces where the active layer 12 is uncovered is 40 μm or less, in the semiconductor light emitting device wherein the ratio of the total area of the side faces 17 to the area of the upper face 15 is 5% or more, in the semiconductor light emitting device including, on the substrate, plural mesa portions where the active layer 12 is spatially separated into plural parts, or in the semiconductor light emitting device including, on the substrate, plural mesa portions where the active layer 12 is spatially separated into plural parts except its bridge portion(s), light going out from the side faces is not easily attenuated; therefore, the effect of improving the external quantum efficiency is high.

### EMBODIMENT 7

The present embodiment is a semiconductor light emitting device which sequentially includes at least a substrate, a first semiconductor layer, an active layer, and a second semiconductor layer, wherein the second semiconductor layer has a polarity different from that of the first semiconductor layer, and one of interior angles made by the side faces where the active layer is uncovered and the upper face which is uncovered at the side of the second semiconductor layer is 138 degrees or more, thereby enlarging the external quantum efficiency.

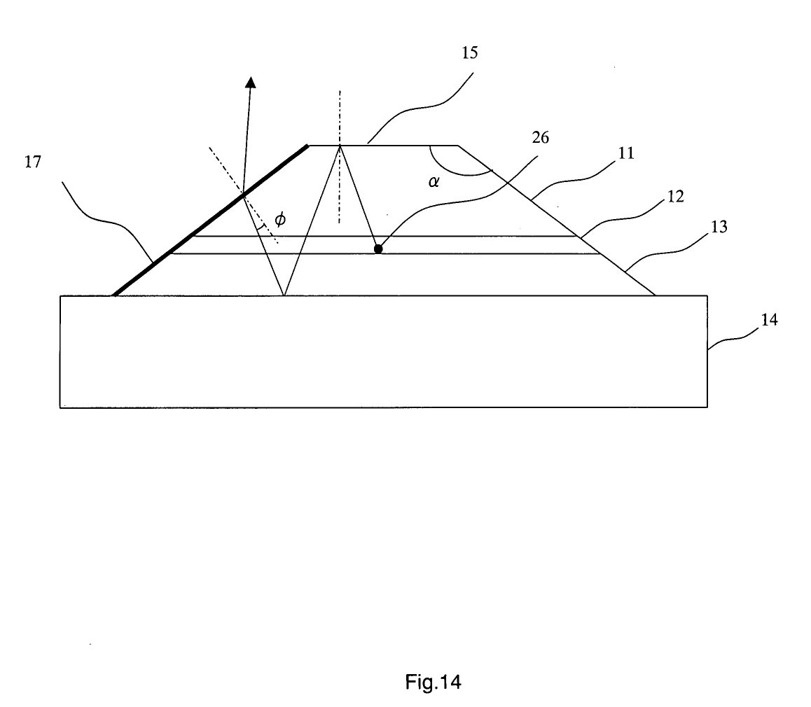

An example of the external form model of the semiconductor light emitting device of the invention is illustrated in FIG. 14.

In FIG. 14, 11 represents a second semiconductor layer; 12, an active layer; 13, a first semiconductor layer; 14, a substrate; 15, an uncovered upper face at the side of the second semiconductor layer; 17, a side face where the active layer is uncovered; and 26, a point light source. The point light source 26 is an imaginary point, at the position of which light is generated. The side face 17, as illustrated in FIG. 14, is obtained by etching under conditions that the difference of selected ratio between lengthwise and lateral selection ratios is small.

In FIG. 14, the first semiconductor layer 17, the active layer 12 and the second semiconductor layer 11 are formed on the substrate 14. The second semiconductor layer 11 and the first semiconductor layer 13 are each a p type or n type semiconductor layer. Polarities thereof are different from each other. At this time, holes supplied from the p type semiconductor layer are recombined with electrons supplied from the n type semiconductor layer in the active layer 12 so as to generate light. As described with reference to FIG. 14, for example, light generated in the point light source 26 in the active layer 12 goes out from the upper face at the side of the second semiconductor layer 11, or is propagated in the second semiconductor layer 11 and the first semiconductor layer 13 so as to go out from the side faces of each of the semiconductor layers.

In the embodiment, about a nitride semiconductor emitting device wherein the second semiconductor layer 11 is combined of a GaN layer (refractive index: 2.8) and an AlGaN layer (refractive index: 2.65); the active layer 12 is made of a GaInN layer (refractive index: 2.8); and the first semiconductor layer 13 is made of a GaN layer (refractive index: 2.8) in FIG. 14, the optimal value of the interior angle made by the side faces 17 and the upper face 15 is obtained in the state that the reflectivity of the bottom face of the first semiconductor layer 13 is set to 100%.

The condition that light generated in the active layer 12 is reflected, on the upper face at the side of the second semiconductor layer 11, at the critical angle of total reflection, is reflected on the bottom face of the first semiconductor layer 13, and then goes into the side faces at an incidence angle of φ which is not more than 21 degrees, which is the critical angle of total reflection, is as follows: α≧138. If the incidence angle to the side faces 17 is less than 21 degrees, the light is not totally reflected on the side faces, so as to go out into outside air.

Accordingly, in the semiconductor light emitting device wherein the semiconductor layers including the active layer 12 are formed on the substrate 14, the second semiconductor layer 11 has a polarity different from that of the first semiconductor layer 17, and the interior angles made by the side faces 17 and the upper face 15 are set to 138 degrees or more, the external quantum efficiency can be made large. In particular, in the semiconductor light emitting device wherein the shortest distance from all points contained in the active layer 12 to the side faces where the active layer 12 is uncovered is 40 82 m or less, in the semiconductor light emitting device wherein the ratio of the total area of the side faces 17 to the area of the upper face 15 is 5% or more, in the semiconductor light emitting device including, on the substrate, plural mesa portions where the active layer 12 is spatially separated into plural parts, or in the semiconductor light emitting device including, on the substrate, plural mesa portions where the active layer 12 is spatially separated into plural parts except its bridge portion(s), light going out from the side faces is not easily attenuated; therefore, the effect of improving the external quantum efficiency is high.

### EMBODIMENT 8

The present embodiment is a semiconductor light emitting device which sequentially includes at least a substrate, a first semiconductor layer, an active layer, and a second semiconductor layer, wherein the second semiconductor layer has a polarity different from that of the first semiconductor layer, and the face of the substrate opposite to the face of the substrate where the first semiconductor layer is formed has thereon a reflecting layer, thereby enlarging the external quantum efficiency.

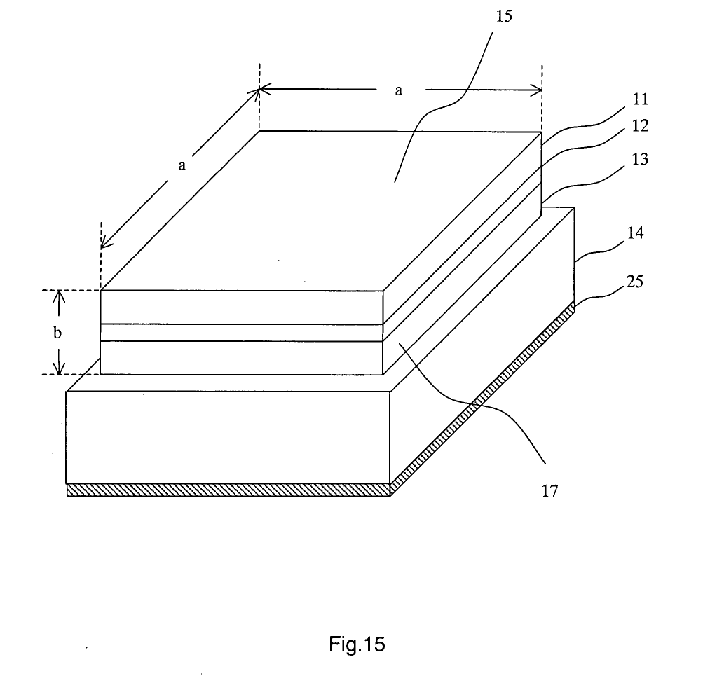

In FIG. 15, a second semiconductor layer 11 including an active layer 12, and a first semiconductor layer 13 are formed on a substrate 14. The second semiconductor layer 11 and the first semiconductor layer 13 are each a p type or n type semiconductor layer. Polarities thereof are different from each other. At this time, holes supplied from the p type semiconductor layer are recombined with electrons supplied from the n type semiconductor layer in the active layer 12 so as to generate light. The generated light goes out from the upper face at the side of the second semiconductor layer 11, or goes toward the substrate 14. The light going toward the substrate 14 is reflected on the substrate in the case that the substrate 14 is a metal substrate. When a reflecting layer 25 is formed on the face of the substrate 14 opposite to the face of the substrate on which the semiconductor layers are formed, the light going toward the substrate 14 is reflected on the reflecting layer 25 in the case that the substrate 14 is made of a transparent material.

When light generated in the active layer 12 is reflected, on the upper face at the side of the second semiconductor layer 11, at the critical angle of total reflection or is reflected on the reflecting layer 25 so as to go into the side faces 17 at an incidence angle of φ which is smaller than 21 degrees, which is the critical angle of total reflection, the light is not totally reflected on the side faces 17 so as to go out into outside air.

Accordingly, in the semiconductor light emitting device wherein the semiconductor layers including the active layers 12 are formed on the substrate 14, the second semiconductor layer 11 has a polarity different from that of the first semiconductor layer 17, and the face of the substrate 14 opposite to the face of the substrate 14 where the semiconductor layers are formed has the reflecting layer 25 thereon, the external quantum efficiency can be made large. In particular, in the semiconductor light emitting device wherein the shortest distance from all points contained in the active layer 12 to the side fades where the active layer 12 is uncovered is 40 μm or less, in the semiconductor light emitting device wherein the ratio of the total area of the side faces 17 to the area of the upper face 15 is 5% or more, in the semiconductor light emitting device including, on the substrate, plural mesa portions where the active layer 12 is spatially separated into plural parts, or in the semiconductor light emitting device including, on the substrate, plural mesa portions where the active layer 12 is spatially separated into plural parts except its bridge portion(s), light going out from the side faces is not easily attenuated; therefore, the effect of improving the external quantum efficiency is high.

### EXAMPLES

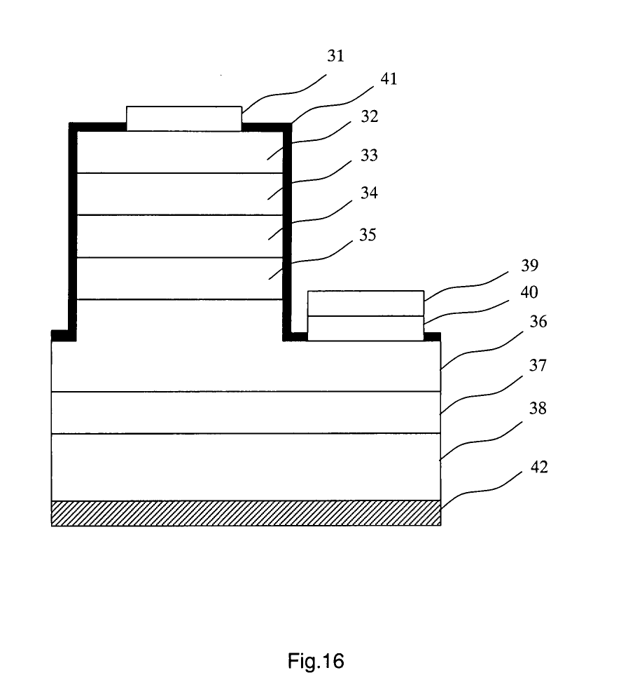

A group III Nitride Compound Semiconductor light emitting device of the invention represented by AlₓGa_{y}In_{1-x-y}N wherein (0≦x≦1, 0≦y≦1, and 0≦x+y≦1) was able to be produced by the following process. The structure of the produced semiconductor light emitting device is illustrated in FIG. 16. With reference to FIG. 16, a description will be made.

Hydrogen gas (H₂), which is a carrier gas, trimethylgallium (TMG), which is an organometallic compound gas, and ammonia (NH₃), which is are action gas, are supplied, as starting material gases, onto a sapphire substrate 38 as a substrate at a temperature of 400 to 700° C., so as to form a layer, about 0.01 to 0.2 μm in thickness, made of GaN by an organometallic compound gas phase growing method. The GaN layer is a GaN low-temperature buffer layer 37 as a part of a semiconductor layer of a semiconductor light emitting device. At the time of the formation of the sapphire substrate 38, Si as a dopant may be added thereto if necessary by the supply of SiH₄. In the case that a metallic reflecting layer 42 is formed on the face opposite to the sapphire substrate face of the semiconductor light emitting device where the GaN low-temperature buffer layer 37 is formed, the metallic reflecting layer 42 is previously formed by the evaporation of a metal before the formation of the GaN low-temperature buffer layer 37.

Next, SiH₄ as a dopant is supplied together with the above-mentioned starting material gases at a temperature of 900 to 1200° C., so as to form a layer, about 2 to 5 μm in thickness, made of n-GaN:Si. The n-GaN:Si layer is an n-GaN:Si high-temperature buffer layer 36 as a part of the semiconductor layer of the semiconductor light emitting device.

Next, trimethylindium is introduced together with the starting material gases to form a layer, about 0.002 to 0.1 μm in thickness, made of a material having a band gap energy which will be smaller than that of the semiconductor layer, for example, a layer made of In_{1-y}Ga_{y}N (0<y≦1). The In_{1-y}Ga_{y}N active layer is an In_{1-y}Ga_{y}N active layer 35 as an active layer of the semiconductor light emitting device.

Next, cyclopentadienylmagnesium (Cp₂Mg) is supplied together with the above-mentioned starting material gases to form a layer, about 0.01 82 m in thickness, made of AlₓGa₁₋ₓN (0<y≦1):Mg. The AlₓGa₁₋ₓN (0<X≦1):Mg layer is an AlₓGa₁₋ₓN:Mg as a part of the semiconductor layer 34 of the semiconductor light emitting device.

Next, cyclopentadienylmagnesium (Cp₂Mg) is supplied as a p type dopant together with the above-mentioned starting material gases to form a layer, about 0.3 to 1 μm in thickness, made of p-GaN:Mg. The p-GaN:Mg layer is a p-GaN:Mg contact layer 33 as a part of the semiconductor layer of the semiconductor light emitting device.

Furthermore, the resultant is annealed at 400 to 800° C., and dopants in the AlₓGa₁₋ₓN:Mg semiconductor layer 34 and the p-GaN contact layer 33 are activated. The p type layer of the nitride semiconductor device, which is made of the group III Nitride Compound, is doped with Mg or the like as the dopant; however, Mg or the like is combined with H of H₂, which is the carrier gas, and NH₃, which is the reaction gas at the time of the doping, so as to give a high resistance without functioning as the dopant. Thus, the annealing is performed in order to separate Mg and H from each other, thereby releasing H to give a low resistance.

Next, Ni/Au is formed by evaporation as a p type electrode. The evaporated Ni/Au is a Ni/Au p type electrode 32.

Next, a resist is applied thereto in order to form an n type electrode, and patterned. Parts of the grown semiconductor layer, the active layer and the p type electrode are then removed by dryetching, so as to make the n-GaN:Si high-temperature buffer layer 36 naked. Furthermore, a resist is applied thereto and patterned. Ni/Au is then formed by evaporation. The layer is subjected to lifting-off to be turned into an Al/Au n type electrode 40. In this case, the parts of the semiconductor layer and so on are removed by the dry etching, but other methods, such as wet etching, may be used in accordance with the material for forming the semiconductor layer.

In the case that plural mesa portions or concaves are made on the substrate, patterning is performed correspondingly to each of the mesa portions or the concaves. In order to form a current diffusing layer for diffusing electric current on the upper face of the semiconductor layer in the mesa portions, bridge portions are patterned so as to connect the mesa portions to each other. At this time, the Ni/Au p type electrode 32 becomes a p side current diffusing layer and the n-GaN:Si high-temperature buffer layer 36 becomes an n side current diffusing layer. In the case of causing the upper face of the semiconductor layer to have an apex having an angle of less than 45 degrees, patterning is performed in accordance with the shape.

Next, a resist is applied thereto and patterning is performed. Ti/Au is formed by evaporation. The resultant is subjected to lifting-off to form Ti/Au bonding pads 31 and 39. The formation of the current diffusing layer and the bonding pads may be used by any other method, such as wet etching, besides dry etching.

Next, in order to attain ohmic contact between the electrode metals and the group III Nitride Compound Semiconductor and make the Ni/Au p type electrode semitransparent, annealing is conducted at about 300° C. Next, a SiO₂ film is formed as a passivation film 41. In order to make the Ti/Au bonding pads 31 and 39 naked, patterning is performed by use of a resist and then portions corresponding to the Ti/Au bonding pads 31 and 39 are wet-etched with an etchant such as hydrofluoric acid. The whole, including the sapphire substrate, is diced to make chips. In this way, a semiconductor light emitting device of the invention can be obtained.

### INDUSTRIAL APPLICABILITY

The semiconductor light emitting device of the invention can be used as an LED.

1. A semiconductor light emitting device, comprising a substrate, and at least a first semiconductor layer, an active layer and a second semiconductor layer that are sequentially provided on the substrate,
wherein the second semiconductor layer has a polarity different from that of the first semiconductor layer, and a total area of the first semiconductor layer, the active layer and the second semiconductor layer in side faces where the active layer is uncovered is 5% or more of an area of an upper face which is uncovered at a side of the second semiconductor layer.

2. A semiconductor light emitting device, comprising a substrate, and at least a first semiconductor layer, an active layer and a second semiconductor layer that are sequentially provided on the substrate,
wherein the second semiconductor layer has a polarity different from that of the first semiconductor layer, and a shortest distance from all points contained in the active layer to side faces where the active layer is uncovered is 40 μm or less.

3. A semiconductor light emitting device, comprising a substrate, and at least two or more mesa portions in each of which a first semiconductor layer, an active layer and a second semiconductor layer that are sequentially provided on the substrate,
wherein the second semiconductor layers have a polarity different from that of the first semiconductor layers and further the second semiconductor layers and the active layers are spatially separated between the mesa portions.

4. A semiconductor light emitting device, comprising a substrate, and at least two or more mesa portions in each of which a first semiconductor layer, an active layer and a second semiconductor layer that are sequentially provided on the substrate,
wherein the second semiconductor layers have a polarity different from that of the first semiconductor layers and further except one or more bridge portions for connecting the mesa portions the second semiconductor layers and the active layers are spatially separated between the mesa portions.

5. A semiconductor light emitting device, which sequentially comprises at least a substrate, a first semiconductor layer, an active layer, and a second semiconductor layer,
wherein the second semiconductor layer has a polarity different from that of the first semiconductor layer, and an upper face which is uncovered at a side of the second semiconductor layer has a concave extending from the uncovered upper face at the side of the second semiconductor layer at least to the active layer.

6. The semiconductor light emitting device according to any one of claims 2 to 4,
wherein a total area of the first semiconductor layer, the active layer and the second semiconductor layer in side faces where the active layer is uncovered is 5% or more of an area of an uncovered upper face at a side of the second semiconductor layer.

7. The semiconductor light emitting device according to any one of claims 3 to 5,
wherein a shortest distance from all points contained in the active layer to side faces where the active layer is uncovered is 40 μm or less.

8. The semiconductor light emitting device according to any one of claims 1, 2, and 5,
wherein a shape of the uncovered upper face at the side of the second semiconductor layer has an apex having an angle of less than 45 degrees.

9. The semiconductor light emitting device according to any one of claims 1, 2, and 5,
wherein one of interior angles made by the side faces where the active layer is uncovered and the uncovered upper face at the side of the second semiconductor layer is 138 degrees or more.

10. The semiconductor light emitting device according to any one of claims 1 to 5,
wherein a face of the substrate opposite to a face of the substrate where the first semiconductor layer is formed has a reflecting layer.

11. The semiconductor light emitting device according to any one of claims 1 to 5,
which is a group III Nitride Compound Semiconductor light emitting device represented by AlₓGa_{y}In_{1-x-y}N wherein (0≦x≦1, 0≦y≦1, and 0≦x+y≦1).

12. The semiconductor light emitting device according to claim 5,
wherein a total area of the first semiconductor layer, the active layer and the second semiconductor layer in side faces where the active layer is uncovered is 5% or more of the area of the uncovered upper face at the side of the second semiconductor layer.

13. The semiconductor light emitting device according to any one of claims 3 and 4,
wherein a shape of an uncovered upper face at a side of the second semiconductor layer has an apex having an angle of less than 45 degrees.

14. The semiconductor light emitting device according to any one of claims 3 and 4,
wherein one of interior angles made by side faces where the active layer is uncovered and an uncovered upper face at a side of the second semiconductor layer is 138 degrees or more.
